(19) United States
(12) Patent Application Publication
(10) Pub. No.: US 2024/0310464 A1
(43) Pub. Date: Sep. 19, 2024

(54) MAGNET SYSTEM

(71) Applicant: Oxford Instruments Nanotechnology Tools Limited, Abingdon, Oxfordshire (GB)

(72) Inventor: Andrew John Varney, Abingdon Oxfordshire (GB)

(21) Appl. No.: 18/575,128

(22) PCT Filed: Jun. 29, 2022
(86) PCT No.: PCT/GB2022/051665

§ 371 Date: Dec. 28, 2023

(30) Foreign Application Priority Data
Jun. 30, 2021 (GB) 2109447.9

(51) Int. Cl. G01R 33/3875; G01R 33/3815; H01F 6/06

(52) U.S. Cl. CPC G01R 33/3875; G01R 33/3815; H01F 6/06

(57) ABSTRACT

There is provided a magnet system for generating a homogeneous magnetic field in a target region. The magnet system comprises: a first magnet formed from low temperature superconductor, LTS, material wound so as to define a central axis, the first magnet being arranged in use to generate a first magnetic field in the target region located upon the central axis, the first magnetic field having a first level of homogeneity; and a second magnet formed from high temperature superconductor, HTS, material and arranged in use to generate a second magnetic field in the target region, the second magnetic field having a second level of homogeneity. The first level of homogeneity of the first magnetic field is up to 10 parts per million, ppm, and the second level of homogeneity of the second magnetic field is up to 10 ppm, the combination of the first and second magnetic fields in the target region generating in use a resultant magnetic field having a resultant homogeneity of up to 10 ppm, and the first magnet and second magnet are independent current circuits.

### FIELD OF THE INVENTION

The present disclosure relates to a magnet system, such as a superconducting magnet system, able to be used for Nuclear Magnetic Resonance (NMR).

### BACKGROUND

It is desirable to obtain a highly homogeneous magnetic field in various NMR modalities. This includes Magnetic Resonance Imaging (MRI), but is especially relevant in NMR spectroscopy.

NMR spectroscopy enables chemical information about samples, such as their molecular structure, to be measured. This NMR measurement process is achieved by generating a high strength, uniform (also referred to as homogeneous) magnetic field within a working volume containing a target region, which working volume is typically a bore in an NMR device.

To analyse a sample, the sample is located in the target region and then subjected to RF irradiation causing the spins of certain nuclei to precess. On removing the RF irradiation, the spins return to their rest state and their precession frequency can be monitored, thus giving an indication of structural information and the like. A highly homogeneous magnetic field is required within the target region to obtain accurate measurements e.g. of the chemical structure.

The magnet system for an NMR device typically comprises a superconducting magnet arrangement held at cryogenic temperatures (for example below 100 kelvin, K) in use. The superconducting magnet is typically formed as a solenoid defining a bore with a central axis along which the working volume for positioning the sample is arranged. An infinitely long solenoid would produce a perfectly homogeneous magnetic field in the target region. However, such solenoids cannot be manufactured in practice and so compensation coils may be wound about the central axis for correcting any end effects from the solenoid, in particular the end effects, to improve the magnetic field homogeneity at the target region.

Compensation coils (also sometimes referred to in the art as “Garrett coils”) are typically wound in series with the magnet and may take the form of solenoids or pancake coils. These are usually arranged to correct for any inhomogeneity in the magnetic field arising from the design of the magnet not being able to be infinitely long. For applications such as high resolution NMR, the solenoid magnet alone, even with the compensation coils typically does not provide the desired level of homogeneity, e.g. due to deviations introduced during the manufacturing process compared to the design. They are also unable to react to shifts in homogeneity during use of a magnet system, e.g. due to environmental variations in magnetic field. Additional measures to correct for sources of inhomogeneity are therefore typically used, such as superconducting shim coils constructed from superconducting wire, passive shims using ferromagnetic material and room temperature shim coils wound from copper wire.

To achieve very high field strengths, such as field strengths above about 23.5 tesla (T), which are desirable for very sensitive NMR in applications, such as structural and functional investigation of large proteins, a combination of low temperature superconductor (LTS) magnets and high temperature superconductor (HTS) magnets are needed. However, partly due to the expense of the materials (and for layer-winding the availability of longer lengths of material while avoiding the need for joints to be constructed within the windings themselves), HTS solenoid coils tend to be short and they also operate at high current density. Hence, if uncompensated, they generate a relatively large amount of inhomogeneity for their size.

LTS coils can be designed to compensate for the inhomogeneity of the whole HTS and LTS magnet combination. This means that the HTS and the LTS coils as separate units remain inhomogeneous. Remaining inhomogeneity could result in a very small axial offset (such as about 0.1 millimetres, mm) of an HTS coil compared to the LTS coil leading to a central field inhomogeneity outside of the suitable limits. Further, if the HTS and LTS coil are run at different currents (for investigation and/or to make most efficient use of the different properties of the materials), the homogeneity will change significantly as the central field is changed unless the currents are held at a fixed ratio. This also means that changes in the operating current of either of HTS or LTS magnet (for example, due to power supply fluctuations) will result in changing magnet homogeneity as well as central field value, and conventional means to compensate for central field changes (for example “NMR lock”) can be much harder to implement if the magnetic field homogeneity is changing significantly as well as the central field value. Additionally, compensation coils tend to exhibit high axial forces and pressures due to the radial field generated, which can lead to quenching due to movements induced by such forces, especially in the higher field regions of the magnet. Coils built from HTS materials are expected to be much more robust to this latter consequence however.

A further point is that an HTS magnet constructed solely from pancake coils will be inherently non-uniform in respect of current density. This makes it much harder to be made usable for conventional NMR applications due to the effects of deviations in current density compared to the theoretical design. This is in part due to the way the current flows in such structures and in part due to manufacturing tolerances.

In view of these difficulties, in order to obtain more accurate, higher resolution NMR data, it is desirable to further increase the magnetic field homogeneity at the target region and stability of homogeneity.

### SUMMARY OF INVENTION

According to a first aspect, there is provided a magnet system for (i.e. suitable for) generating a homogeneous magnetic field in a target region, the magnet system comprising: a first magnet formed from low temperature superconductor (LTS) material and formed (such as wound) so as to define a central axis, the first magnet being arranged in use to generate a first magnetic field in the target region located upon the central axis, the first magnetic field having a first level of homogeneity; a second magnet formed from high temperature superconductor (HTS) material and arranged in use to generate a second magnetic field in the target region, the second magnetic field having a second level of homogeneity, wherein the first level of homogeneity of the first magnetic field is up to 10 parts per million, ppm, and the second level of homogeneity of the second magnetic field is up to 10 ppm, the combination of the first and second magnetic fields in the target region generating in use a resultant magnetic field having a resultant homogeneity of up to 10 ppm, and wherein the first magnet and second magnet are independent current circuits.

We have found that by configuring a magnet system in this manner, the resultant homogeneity is able to be retained within the wanted parameters even when there is a cause of inhomogeneity in one or other of the first and second superconducting magnets (such as an offset of a magnet or a current variation in a magnet). This is achieved by correcting the inhomogeneity of each of the first superconducting magnet and second superconducting magnets (i.e. by achieving up to a particular homogeneity level) in its own right.

Without this arrangement, when two superconducting magnets are run as separate current circuits, each superconducting magnet will contribute to the total inhomogeneity (a resultant homogeneity) at a target region. This results in the total inhomogeneity being the proportional sum of the inhomogeneity of each of the first and second superconducting magnets.

In that situation, inhomogeneity in one of two such superconducting magnets would then need to be corrected. This is achieved by applying compensation coils, which are run in series with one of the two superconducting magnets, and thereby in the same current circuit as the respective one superconducting magnet. Using this principle, the inhomogeneity of that one superconducting magnet is engineered to cancel the inhomogeneity of the other of the two superconducting magnets in order to meet a resultant homogeneity level specification. In a similar situation, should a plurality of superconducting magnets be (electrically) connected in series, such as being forming part of the same current circuit, any changes applied to the homogeneity or that affects the homogeneity of one of the superconducting magnets has a knock-on effect on the homogeneity of each of the other superconducting magnets of the plurality of superconducting magnets.

Unlike a magnet system according to the first aspect, if there is then a variation in the contribution to the resultant homogeneity level of one of the two superconducting magnets, the inhomogeneity of the whole assembly is no longer corrected as completely or to the same degree. The cause of such a variation could, for example, be due to a relative offset or a change in the operating current of at least one of the superconducting magnets. The reason the correction would not be as complete is because the cancellation will no longer be as complete or able to be as complete. However, without applying what we have found, it is not possible to reduce such a change in degree of correction.

Instead, by adopting an arrangement according to the first aspect, changes that would alter homogeneity, such as changes caused by a movement of a magnet or a change in operating current, either have no effect on the homogeneity of the magnet to which the change occurs or only affect the homogeneity of the magnet to which the change occurs. Therefore, any effect on homogeneity of, for example, the resultant magnetic field is significantly limited. Accordingly, this reduces any cause of inhomogeneity in a magnet system with non-independent homogeneities that would otherwise produce an unacceptable overall homogeneity level should the homogeneities be interdependent. As such, the overall homogeneity of the magnet is improved and the magnet system is made more resilient to causes of inhomogeneity.

The target region may have a size of about a 0.5 centimetre (cm) diameter spherical volume (dsv) to about a 2 cm dsv, such as a 1 cm dsv. The target region may typically be centred on a centre point of the central axis, which typically is the geometrical centre of the first magnet (and typically also of the second magnet). Homogeneity as referred to herein is typically measured by considering variations in the magnetic field strength of the z-component (i.e. Bz) of a magnetic field (which is the primary field direction) within a spherical target region with respect to the field at the centre of that region. For instance, a magnetic field having a homogeneity of up to 10 ppm in the target region has a Bz component varying by less than 10 parts per million at any position within the target region (i.e. the difference between the maximum field within the target region and the minimum field within the target region is less than 10 ppm of the field value at the origin of that region).

The variation of magnetic field over a region (such as the target region) can be analysed in terms of spherical harmonics. The magnetic field at any point in that region being the sum of the components. Additionally, the overall homogeneity over that region (for example the 10 ppm referred to above) is defined by the maximum variation within that region. Each component of the field (i.e. the spherical harmonics) will contribute differently to the homogeneity. Taking the Z2 component as an example, this varies as the square of the distance along the axis, so will have the same value at both +1 cm and −1 cm. Considering a 1 cm dsv, the maximum value will for this component will be at +/−0.5 cm, and so if Z2 were the only contribution to the inhomogeneity, a Z2 of 4 ppm/cm\hat{ }2 (each component having a unit of ppm/cm\hat{ }n, where n is the component spherical harmonic order) would correspond to a value of 1 ppm over 1 cm dsv.

While homogeneity values can be stated as positive or negative values, the first homogeneity and/or the second homogeneity and/or the resultant homogeneity stated above can be thought of as being absolute values. Therefore these are intended to encompass positive and negative homogeneities to the stated level, such as positive or negative 10 ppm for one, two or each of the three stated homogeneities. Other than where a homogeneity or spherical harmonic value is specifically stated as being negative or is stated in the same context as a homogeneity that is stated as being negative, all homogeneities disclosed herein can be thought of as absolute values, and therefore being intended to encompass positive and negative homogeneities of the stated level. As part of this, it can be understood that the smaller the number (i.e. the closer to zero) is for the homogeneity in terms of ppm, the better the homogeneity is. As such, a homogeneity of +1 ppm is better than a homogeneity of +10 ppm, which in turn is better than a homogeneity of +100 ppm. Accordingly, by the term “up to” in relation to a stated homogeneity value is intended to mean the homogeneity is able to be in a range from and including zero to and including the stated homogeneity value.

By the term “LTS material” we intend to mean superconducting materials that allow a maximum field strength of up to at most about 22 T at 4.2 K at an engineering critical current density of 100 amperes per square millimetre (A/mm²). This includes materials such as niobium-titanium (NbTi) and niobium-tin (Nb₃Sn). Some enhancement in performance can be provided for LTS materials by operating them below 4.2 K. However, for NbTi and Nb₃Sn this only raises the maximum field strength limit by about 2 to 2.5 T. The engineering critical current density of Nb₃Sn drops abruptly at field strengths above about 20 T making this material much less efficient above about 20 T and unusable above about 23.5 T at 4.2 K.

The term “HTS material” is intended to mean superconducting materials that show nominally usable superconducting properties beyond 30 T and even 40 T (and at temperatures of about 4.2 K or below, and typically at temperatures above about 4.2 K, such as at 8 K, 20 K, 77 K or 90 K). Such materials include rare-earth barium copper oxide (REBCO) and bismuth strontium calcium copper oxide (BSCCO, e.g. BSCCO 2212 or BSCCO 2223).

As can be seen from the above, HTS materials have a higher critical field in comparison with LTS materials and so the second magnet being formed of an HTS material enables higher magnetic fields to be produced at the target region. This is because, in order to provide a usable magnet system capable of producing a field strength much above about 20 T (greater than 23.5 T for example), with current technology, HTS material is needed. However, since this is orders of magnitude more expensive than the LTS materials, magnet systems are typically a hybrid, with the first 15 T to 20 T provided by LTS windings.

Although HTS material remains superconducting at higher temperatures than LTS material, it is typically most convenient to hold the first and second magnets at a common temperature in use. The first and second magnets therefore may be contained within the same cryogenic vessel, such as a Dewar, configured to cool the first and second magnets to a common temperature in use. Typically the cryogenic vessel is filled with liquid helium to cool the first and second magnets to approximately 4 K (such as 4.2 K) in use. However, a cryogen-free refrigerator, such as pulse tube refrigerator, can alternatively be used to cool the first and/or second magnets.

We intend the term “independent current circuit” to mean circuits that are separate, and therefore do not have any joint or physical connection as part of a circuit therebetween. As such, independent current circuits may be unjointed (with each other). This does not preclude one circuit being inductively chargeable by the other for example, or for the same power supply to be used for each circuit as long as there is some mechanism, such as a potential divider, that allows the independence of the current circuits to be maintained.

The term “offset” is used when discussing a change in homogeneity or a cause of increased inhomogeneity. By the term “offset” we intend to mean a movement or mispositioning of a coil, magnet or portion of a magnet relative to the position in which it was designed to be positioned and/or relative to a further coil, magnet or portion of a magnet. For example, an axial offset of about 1 mm or 0.5 mm of a coil is a movement or positioning of a coil in a direction along coaxial with the central axis of the coil and/or magnet or magnet system from the coil's intended position, either due to physical movement due to forces being experienced by the coil in use or for some other reason, or due to being (inadvertently) incorrectly positioned during construction. Such an offset may be a result of manufacturing tolerances, construction techniques, or, as mentioned, forces experienced by the coil.

The first magnet may have a homogeneity of up to 1 ppm in the target region. Additionally or alternatively, the second magnet may have a homogeneity of up to 1 ppm in the target region. When each of the first and second magnet have a homogeneity of up to 1 ppm, the resultant magnetic field may have a homogeneity of up to 1 ppm. As such, typically, the first level of homogeneity may be up to 1 ppm, the second level of homogeneity may be up to 1 ppm and the resulting homogeneity may be up to 1 ppm. This allows the magnet system to be suitable for use with NMR applications, the exact total homogeneity of the resultant magnetic field typically being dependent on the relative resultant field contribution from the first and second magnets.

As a comparison in a “perfect” system, such as one in which the first magnet and second magnet are each perfectly homogeneous, the effects of changes in position or current of either magnet would have zero effect on the homogeneity of the combined magnet. An aim of a magnetic system according to an aspect disclosed herein is to achieve as close as is practical to this perfect solution.

Taking every-day practicalities into account, realistically, this means limiting the change required for such a magnet system to be suitable for the application (such as to a homogeneity limit of 1 ppm or 10 ppm).

The magnet system may further comprise a control system arranged to provide a first current in the first magnet, and a second current in the second magnet, and wherein the first and second currents are controlled independently of each other. This provides a means of administering separate currents to the independent current circuits and an ability to control the current supplied to each of the first magnet and the second magnet.

The magnet system may have (only) a single power supply to which each of the first magnet and second magnet are connected in parallel in order for independent current circuits to be provided. As alluded to above, this could be achieved using a potential divider. Alternatively, a single power supply may be connected to only one of the first or second magnet, such as the first magnet, which may be arranged in use to inductively charge the second magnet while still allowing independent current circuits to be maintained. Typically however, the magnet system may further comprise a first power supply arranged in use to provide power to the first magnet and a second power supply arranged in use to provide power to the second magnet, the first power supply and second power supply being independent of each other. This further separates the independent current circuits from each other making it easier to provide independent control of each current circuit and to reduce unintended coupling between the first magnet and second magnet.

The first magnet may comprise bulk superconductors or various magnet geometries. Typically, the first magnet may be a wound magnet. As such, the first magnet may comprise a first compensated solenoid magnet. This allows greater precision and predictability of the homogeneity of the first magnet.

The first magnet may comprise a plurality of solenoids formed from superconductor material wound about the central axis (and outside of the bore), wherein each said solenoid is disposed at a respective radial position. An outermost solenoid of the first magnet may be formed from NbTi. NbTi is relatively much less brittle than Nb₃Sn and HTS materials, and significantly cheaper, so is desirable in the lower-field region of the magnet system that is radially further from the central axis.

The first magnet may be designed to have a suitable homogeneity based purely on the use of, for example, one or more solenoids, such as layer-wound solenoids. Typically the first compensated solenoid magnet comprises at least one solenoid and a set of first compensation coils, the set of first compensation coils being arranged in use to compensate the at least one solenoid.

Such compensation coils may therefore be provided for correcting a magnetic field inhomogeneity at the target region arising from the design and structure of the first magnet (i.e. due to not being an infinitely long solenoid).

For example, the first magnet may have a first pair of compensation coils, which are connected in electrical series with the first solenoid. The first pair of compensation coils may also be disposed at a radial position from the central axis which is less than that of the first solenoid.

The first solenoid and the first pair of compensation coils may be formed from Nb₃Sn. Nb₃Sn is desirable because of its ability to remain superconducting in a high magnetic flux density. The compensation coils can hence be used in a high-field region of the magnet system.

The second magnet may be any suitable magnetic geometry or include any suitable magnetic geometry, such as bulk superconductors, ferromagnetic material, resistive electromagnets, or superconducting wire or tape. Typically, the second magnet comprises a set of coils, such as a set of coils located upon the central axis (and typically outside of the bore), wherein each coil may be disposed at a respective radial position. The set of coils may be one or more solenoids and/or one or more pancake coils. The solenoids may be layer-wound solenoids. The use of a set of coils allows greater precision and predictability of the homogeneity of the second magnet.

The second magnet may be located coaxially upon the central axis with respect to the first magnet and radially inwardly of the first magnet. This minimises the overall size of the magnet system and allows the contribution to the resultant magnetic field in the target region to be as large as possible.

The second magnet may comprise a second compensated solenoid magnet, including at least one solenoid and a set of second compensation coils which are operated in use so as to provide compensation to the at least one solenoid, and the set of second compensation coils are located according to

$$\sqrt{{( {r}_{p} )}^{2} + {( {z}_{p} )}^{2}} > 2 {r}_{0}$$

where r₀ is the inside radius of the at least one solenoid and, rₚ is the radius of the centre of the a respective compensation coil (of the set of second compensation coils), and zₚ is the axial position of the centre of said compensation coil. Typically, the set of second compensation coils are connected in (electrical) series as part of the current circuit of the second magnet. This is able to compensate for inhomogeneities in the field producible by the at least one solenoid. Such compensation coils may therefore be provided for correcting a magnetic field inhomogeneity at the target region arising from the design of the second magnet.

The set of second compensation coils may be located according to

$$\sqrt{{( {r}_{p} )}^{2} + {( {z}_{p} )}^{2}} > 3 {r}_{0} .$$

The at least one solenoid of the second compensated solenoid magnet may comprise a primary (layer-wound) solenoid coil extending from the axial centre symmetrically axially away from the target region, the set of second compensation coils being pancake coils and located adjacent the primary solenoid coil at axial ends of the primary solenoid coil. In such a case, r₀ may be the inside radius of the primary solenoid coil.

A coil set constructed solely from pancake coils will be inherently non-uniform in respect of current density, making it much harder to be made usable, for example, for conventional NMR applications due to the effects of deviations in current density compared to the theoretical design. This is in part due to the way the current flows in such structures and in part due to manufacturing tolerances. However, the magnitude of these effects seen at the target region of the magnet reduces rapidly with distance from the centre. The described arrangement therefore provides a simple means of providing a compensated second magnet with the desired homogeneity without the need to use technically challenging and expensive layer-wound HTS compensation coils.

Pancake coils are known in the art and arise wherein a conductor is wound in a spiral outwards about an origin and along a common plane. In the present case the origin is positioned along the central axis of the magnet system and the plane is normal to the central axis. Whilst in principle only a single pancake coil may be used, in practice multiple pancake coils are able to be stacked along the axial direction of the magnet. For example, when stacking two pancake coils this forms a “double-pancake”. This occurs where the coil is wound with a conductor that spirals in from the outside of one pancake to the innermost position of a second pancake coil from which the conductor is then wound radially outwards, the second pancake being coaxially arranged with the first pancake and wound in the same direction as the first pancake. If further pancake coils are wound on to the same stack, each coil is connected to adjacent coils in the same manner either at a radially innermost position or at a radially outermost position depending on where the end of the spiral is located for the pancake coil from which it is continuing. In this manner (and for any arrangement of multiple pancake coils so connected) a connected stack of pancake coils is formed.

The second magnet may further comprise a secondary solenoid coil arranged coaxially upon the central axis with respect to the primary solenoid coil and radially inwardly of the primary solenoid coil (but typically outside of the bore). This allows an increased field strength to be achieved while maintaining the desired homogeneity level.

The second compensation coils may comprise a compensation coil located axially outwardly of each end of the primary solenoid coil with at least a partial radial overlap with the primary solenoid coil and/or a compensation coil located radially outwardly of the primary solenoid coil at each axial end of the primary solenoid coil. Similarly to the effect mentioned above, this limits the effect of the pancake coils on the higher order harmonics while allowing improved magnetic field homogeneity of the second magnet to be achieved.

Each second compensation coil may be reverse wound relative to the primary solenoid coil. Typically however, each second compensation coil may be forward wound relative to the primary solenoid coil. This causes each second compensation coil to contribute a positive zeroth order field to the target region.

According to a second aspect, there is provided a magnet system for generating a homogeneous magnetic field in a target region, the magnet system comprising: a first magnet formed from a superconducting material in a cylindrical shape around a central axis, the first magnet being arranged in use to generate a first magnetic field in the target region located upon the central axis; and a set of compensation coils which are operated in use so as to provide the homogeneity of the first magnetic field, wherein the first magnet extends from the axial centre symmetrically axially away from the target region and the set of compensation coils pancake coils located according to are \sqrt{(rₚ)²+(zₚ)²}>2r₀ where r₀ is the inside radius of the first magnet and, rₚ is the radius of the centre of the a respective pancake coil, and zₚ is the axial position of the centre of said pancake coil.

The set of compensation coils may be located adjacent the first magnet at axial ends of the first magnet.

The compensation coils may comprise a compensation coil located axially outwardly of each end of the first magnet with at least a partial radial overlap with the first magnet and/or a compensation coil located radially outwardly of the first magnet at each axial end of the first magnet.

The magnet system according to the second aspect may further comprise a second magnet arranged coaxially upon the central axis with respect to the first magnet and radially inwardly of the first magnet, and optionally the first magnet may be a first solenoid coil and/or the second magnet may be a second solenoid coil.

Each second compensation coil may be forward wound relative to the primary solenoid coil.

The magnet system of the second aspect may provide the second magnet of the first aspect and may include or incorporate any individual feature or combination of the features described above in relation to the second magnet of the first aspect. Additionally or alternatively, the magnet system of the second aspect may be formed of HTS material.

The magnet systems herein described is particularly suitable at high fields and is typically arranged to produce a magnetic field in the target region in excess of 20 T, preferably in excess of 25 T. MRI systems typically use larger samples and so it is generally more relevant to achieve homogeneity over a larger target region in these systems. Consequently, having an extremely high degree of homogeneity over a 1 cm dsv target region is generally not relevant to MRI systems. The magnet system according to at least the first aspect is therefore particularly suitable for use in NMR spectroscopy and typically produces a homogeneity in the target region below 5 ppm, such as below 1 ppm. A third aspect is therefore an NMR spectrometer comprising a magnet system according to the first aspect or the second aspect, which, in an NMR spectrometer typically includes additional components such as superconducting shims to improve the homogeneity still further. The NMR spectrometer may further comprise a cryogenic cooling system configured to cool the magnet system to below 100 K, such as below 10 K, during operation of the NMR spectrometer. The cooling system may be configured to cool the magnet system to below 5 K, such as to 4.2 K or lower (i.e. down to about 2 K in some examples). The magnet system is also suitable for use in other NMR systems, such as Fourier Transform Mass Spectroscopy, FTMR (also referred to as Fourier-Transform Ion Cyclotron resonance, FT-ICR).

### BRIEF DESCRIPTION OF FIGURES

Example magnet systems are described in detail below with reference to the accompanying figures, in which:

FIG. 1 shows a schematic view of a prior art magnet system;

FIG. 2 shows a schematic view of a further prior art magnet system;

FIG. 3 shows a schematic view of a first example magnet system;

FIG. 4 shows a schematic view of a comparative example magnet system to the magnet systems shown in FIGS. 5 to 9;

FIG. 5 shows a schematic view of a second example magnet system;

FIG. 6 shows a schematic view of a third example magnet system;

FIG. 7 shows a schematic view of a fourth example magnet system;

FIG. 8 shows a schematic view of a fifth example magnet system; and

FIG. 9 shows a schematic view of a sixth example magnet system.

### DETAILED DESCRIPTION

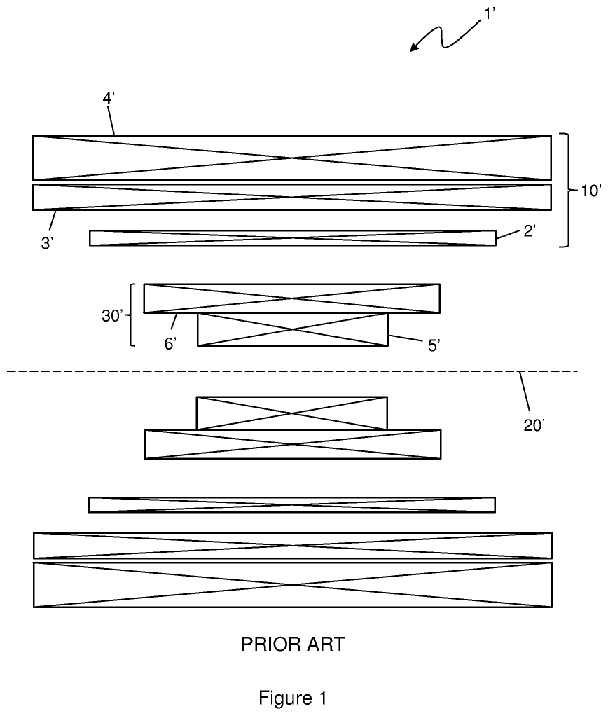

An example of an existing magnet system is generally illustrated at 1′ in FIG. 1. This figure shows a schematic illustration of a cross-section through a cylindrical coil set according to a prior art magnet assembly.

The cross-section is taken along the central axis 20′, which extends along a bore of the magnet. Two sides of the assembly, above and below the bore, are shown in FIG. 1. In all the other figures only one side of the respective magnet assembly or magnet system is shown, although it will be appreciated that the coils are symmetrically arranged on the opposite side of the central axis of each respective assembly or system and are simply not shown in the figures to provide clarity.

The assembly 1′ shown in FIG. 1 has a first superconducting magnet 10′ comprising a first solenoid 2′, second solenoid 3′ and third solenoid 4′. Each of the first, second and third solenoid are formed of an LTS material, such as NbTi and Nb₃Sn.

The first solenoid 2′ is the radially innermost solenoid and the second solenoid 3′ is arranged radially between the first solenoid and the third solenoid 4′. As such, the third solenoid is the radially outermost solenoid. Additionally, the first solenoid also has a radial separation between itself and the second solenoid, whereas the second solenoid and third solenoid are approximately radially adjacent to each other.

In relation to axial space occupied by each solenoid of the first superconducting magnet 10′, the first solenoid 2′ occupies less axial space than each of the second solenoid 3′ and third solenoid 4′, which occupy about the same axial space as each other.

Each solenoid 2′ to 4′ of the first superconducting magnet 10′ is coaxially wound about the central axis 20′. The magnet assembly 1′ also has a second superconducting magnet 30′ with a first coil 5′ and second coil 6′. The coils of the second superconducting magnet are also co-axially wound about the central axis.

The first coil 5′ is the radially innermost coil of the second superconducting magnet 30′. The first coil and second coil 6′ are radially adjacent each other. Additionally, they are arranged radially inwardly of the solenoids 2′, 3′ 4′ of the first superconducting magnet 10′ and are radially separated from the first solenoid 2′.

The first coil 5′ occupies less axial space than the second coil 6′, which in turn occupies less axial space than the first solenoid 2′.

Each of the first coil 5′ and the second coil 6′ are formed of an HTS material, such as BSCCO 2212.

Regarding radial thickness of each of the second to fifth solenoids, the second solenoid 3′, first coil 5′ and second coil 6′ are approximately the same radial thickness as each other. The first solenoid 2′ has a smaller axial length, and the third solenoid 4′ has a larger axial length than these solenoids.

The magnet assembly 1′ shown in FIG. 1 is an uncompensated solenoid magnet assembly.

The magnet assembly 1′ is designed to have a field homogeneity that meets a predetermined specification. An uncompensated magnet assembly as shown in FIG. 1 may be designed to have a homogeneity of less than 100 ppm over a 1 cm dsv.

When the magnetic assembly 1′ is constructed as designed and operating as intended with the first superconducting magnet 10′ and second superconducting magnet 30′ (i.e. the LTS magnet and HTS magnet respectively) operating at predetermined operating currents, Iₒₚ, the contribution to inhomogeneity of the whole magnet assembly in terms of spherical harmonics, in units of ppm/cm\hat{ }n (i.e. the sum of the homogeneities of the LTS and HTS magnets and therefore the homogeneity of the resultant magnetic field) is as shown in Table 1:

TABLE 1

| Magnet | | | | | | | | | |
|---|---|---|---|---|---|---|---|---|---|
| section | Iₒₚ (A) | Z1 | Z2 | Z3 | Z4 | Z5 | Z6 | Z7 | Z8 |
| 10″ | 125 | 0 | −124 | 0 | 0 | 0 | 0 | 0 | 0 |
| 30″ | 350 | 0 | −351 | 0 | −2 | 0 | 0 | 0 | 0 |
| 1″ | | 0 | −475 | 0 | −2 | 0 | 0 | 0 | 0 |

This provides an example with the spherical harmonic components provided in the table are a value with respect to the total central field from the whole magnet assembly.

For such magnets, should there be a 1 mm axial offset between the coils of the second superconducting magnet 30′ and the solenoids of the first superconducting magnet 10′ (i.e. between the HTS magnet and the LTS magnet), when each is operating at predetermined operating current, Iₒₚ, the contribution to inhomogeneity of the whole magnet assembly 1′ in terms of spherical harmonics, in units of ppm/cm\hat{ }n (i.e. the sum of the homogeneities of the LTS and HTS magnets and therefore the homogeneity of the resultant magnetic field) is as shown in Table 2:

TABLE 2

| Magnet | | | | | | | | | |
|---|---|---|---|---|---|---|---|---|---|
| section | Iₒₚ (A) | Z1 | Z2 | Z3 | Z4 | Z5 | Z6 | Z7 | Z8 |
| 10″ | 125 | 0 | −124 | 0 | 0 | 0 | 0 | 0 | 0 |
| 30″ | 350 | 70 | −351 | 1 | −2 | 0 | 0 | 0 | 0 |
| 1″ | | 70 | −475 | 1 | −2 | 0 | 0 | 0 | 0 |

As with Table 1, Table 2 provides an example with the spherical harmonic components provided in the table are a value with respect to the total central field from the whole magnet assembly. In line with the details set out above, for example, the Z1 harmonic has a unit of ppm/cm, the Z2 harmonic has a unit of ppm/cm², the Z3 harmonic has a unit of ppm/cm³ and so on. This also applies to the corresponding values in Tables 2 and 3 below.

As can be seen from comparing Table 1 and Table 2, a 1 mm axial offset of the coils of the second superconducting magnet 30′ relative to the solenoids of the first superconducting magnet 10′ produces a homogeneity of 70 ppm/cm in the Z1 harmonic and a homogeneity of 1 ppm/cm³ in the Z3 harmonic. The change of 70 ppm/cm in the Z1 harmonic is a significant change in homogeneity for a small offset.

Additionally, should there be a current fluctuation in the second super conducting magnet, since this has a homogeneity of 351 ppm/cm² in the Z2 harmonic (due to the design of the second superconducting magnet since the magnet assembly of FIG. 1 is not compensated), if there is a 1% fluctuation in operating current, this could lead to a change of the homogeneity in the Z2 spherical harmonic of more than 3 ppm/cm². There is little effect on the Z2 spherical harmonic due to any axial offset between the first and second superconducting magnets however.

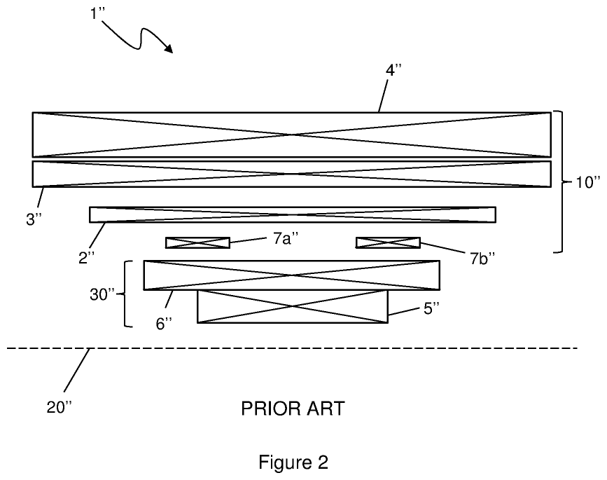

The “100 ppm magnet” represented by the prior art magnet assembly 1′ shown in FIG. 1 is able to be turned into a “1 ppm magnet” (i.e. a magnet assembly with a magnetic field homogeneity of about 1 ppm) by compensating the magnet. An example of such a magnet assembly is generally illustrated at 1″ in FIG. 2. As set out above, this figure, as with each subsequent figure, only shows the configuration of magnets on one side of the central axis.

The magnet assembly 1″ shown in FIG. 2 has a first superconducting magnet 10″ and a second superconducting magnet 30″. The second superconducting magnet has exactly the same configuration of coils as the magnet assembly 1′ of FIG. 1. As such, second superconducting magnet 30″ shown in FIG. 2 has coils 5″ and 6″ co-axially wound about a central axis 20″ and each is formed of HTS material.

Turning to the first superconducting magnet 10″ of the magnet assembly 1″ of FIG. 2, this has a first solenoid 2″, second solenoid 3″ and third solenoid 4″ in the same configuration and composition as the first superconducting magnet 10′ of the magnet assembly 1′ of FIG. 1. In addition to the first to third solenoids however, the first superconducting magnet shown in FIG. 2 also has a first compensation coil 7a″ and a second compensation coil 7b″.

The compensation coils 7a″, 7b″ are coaxially wound around the central axis 20″ and are located radially inwardly of the first solenoid 2″. Each compensation coil is formed of LTS material, and is connected in series with the solenoids 2″, 3″, 4″.

The compensation coils 7a″, 7b″ are positioned at the same radial position as each other. In terms of axial position, the compensation coils are axially located equidistant from the axial centre of the central axis 20″ and occupy the same amount of axial space and radial thickness as each other. Accordingly, the compensation coils are symmetrically positioned with an axial offset about a geometrical centre point along the central axis 20″. This is to cancel out the odd axial orders (such as Z3 for example) of inhomogeneity.

Additionally, the radial thickness of the compensation coils is about the same as the radial thickness as the first solenoid 2″ radial thickness. The axial centres of each compensation coils approximately aligns with the axial ends of the first coil 5″ of the second superconducting magnet 30″. These compensation coils provide compensation for the solenoids 2″, 3″, 4″ of the first superconducting magnet 10″ and for the second superconducting magnet 30″.

When the magnetic assembly 1″ is constructed as designed and operating as intended with the first superconducting magnet 10″ and second superconducting magnet 30″ operating at predetermined operating currents, Iₒₚ, the homogeneity in the spherical harmonics for the magnetic field of each superconducting magnet and overall for the whole magnet assembly is as shown in Table 3:

TABLE 3

| Magnet | | | | | | | | | |
|---|---|---|---|---|---|---|---|---|---|
| section | Iₒₚ (A) | Z1 | Z2 | Z3 | Z4 | Z5 | Z6 | Z7 | Z8 |
| 10″ | 125 | 0 | 355 | 0 | −1 | 0 | 0 | 0 | 0 |
| 30″ | 350 | 0 | −351 | 0 | −2 | 0 | 0 | 0 | 0 |
| 1″ | | 0 | 4 | 0 | −3 | 0 | 0 | 0 | 0 |

As shown in Table 3, it can be seen that under intended conditions, the magnetic assembly 1″ of FIG. 2 is a 1 ppm magnet (as noted above). This is due to the homogeneity in the Z2 harmonic being 4 ppm/cm², which, as set out above, corresponds to an overall homogeneity for the magnet assembly of about 1 ppm over a 1 cm dsv.

This improvement in the homogeneity compared to the magnetic assembly 1′ of FIG. 1 is provided by the compensation coils 7a″, 7b″. However, when there is a 1 mm axial offset between the coils of the second superconducting magnet 30″ and the first superconducting magnet 10″ is shown in Table 4:

TABLE 4

| Magnet | | | | | | | | | |
|---|---|---|---|---|---|---|---|---|---|
| section | Iₒₚ (A) | Z1 | Z2 | Z3 | Z4 | Z5 | Z6 | Z7 | Z8 |
| 10″ | 125 | 0 | 355 | 0 | −1 | 0 | 0 | 0 | 0 |
| 30″ | 350 | 70 | −351 | 1 | −2 | 0 | 0 | 0 | 0 |
| 1″ | | 70 | 4 | 1 | −3 | 0 | 0 | 0 | 0 |

While there continues to be a reduction in the inhomogeneity in the Z2 spherical harmonic compared to the magnet assembly 1′ of FIG. 1, Table 4 shows that in the Z1 spherical harmonic the inhomogeneity produced by the offset is the same as for the magnet assembly of FIG. 1. Further, with a homogeneity of 351 ppm/cm² in the Z2 harmonic from the second superconducting magnet 30″, a 1% fluctuation in operating current would still lead to a change in homogeneity in the Z2 harmonic of greater than 3 ppm/cm². As such, the addition of compensation coils has little effect on changes in homogeneity caused by axial offsets. This therefore shows that a standard compensated magnetic assembly provides little to no improvement over an uncompensated magnetic assembly when there is even a small offset between the HTS and LTS magnet.

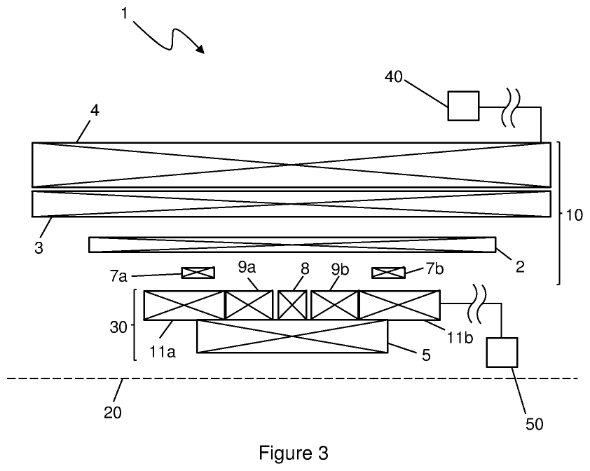

We have found however that homogeneity can be improved by using a magnet system corresponding to an aspect disclosed herein, examples of which are shown in FIGS. 3 and 5 to 9. An example magnet system according to an aspect is generally illustrated a 1 in FIG. 3.

In the example shown in FIG. 3, there is a first superconducting magnet 10. This has an identical configuration of solenoids 2, 3, 4 and compensation coils 7a, 7b to the first superconducting magnet 10″ of the magnet assembly 1″ shown in FIG. 2. This is apart from the compensation coils 7a, 7b in the example of FIG. 3 occupying less axially space than the compensation coils 7a″, 7b″ of the first superconducting magnet shown in FIG. 2. The relationship between the solenoids and compensation coils and the central axis 20 is therefore the same as in FIG. 2. Additionally, the solenoids 2, 3, 4 and compensation coils of the first superconducting magnet shown in the example of FIG. 3 continue to be formed of LTS material.

The example magnet system 1 shown in FIG. 3 also has a second superconducting magnet 30. The second superconducting magnet has a first coil 5 with an identical configuration to the first coils 5′, 5″ of the magnet assemblies 1′, 1″ of FIG. 1 and FIG. 2. Additionally, the first coil shown in FIG. 3 has the same radial and axial relationship with the central axis and first superconducting magnet 10 as is the case for the corresponding coils of FIGS. 1 and 2.

In place of the second coils 6′, 6″ shown in FIGS. 1 and 2, in the example shown in FIG. 3, the second superconducting magnet 30 has five coils. These are each coaxially wound around the central axis 20 and are connected in series with each other and the first coil 5 of the second superconducting magnet. These five coils are located in the same radial position as the second coils of FIGS. 1 and 2. The axial ends of these coils are also located at approximately the same position axially as the second coils of FIGS. 1 and 2. Each of the five coils is formed of HTS material.

The five further coils of the second superconducting magnet 30 in the example of FIG. 3 comprise a central second coil 8. The axial centre of this coil is aligned with the axial centre of the central axis relative to the rest of the magnet system 1 of this example. The central second coil is also has the shortest axial length of the five further coils.

Axially outward of to the central second coil 8, and equidistant from and symmetrically positioned relative thereto are two intermediate second coils 9a, 9b. These are axially spaced apart from the central second coil. The intermediate second coils have the same axial length as each other and have an axial length of approximately two to three times the axial length of the central second coil.

Axially outward of, and adjacent, the axial ends of the two intermediate second coils 9a, 9b there are two outer second coils 11a, 11b. These are symmetrically positioned relative to the central second coil 8 and have the same axial length as each other, which is about twice the axial length of the intermediate second coils. In combination with the axial size of the intermediate and central second coils, this causes the outer second coils to have inner axial ends axially closer to the axial centre than the axial ends of the first coil 5. The outer axial ends of the outer second coils project axially outward of the axial ends of the first coil by approximately a quarter of the axial length of the first coil. The central, intermediate and outer axial coils 8, 9a, 9b, 11a, 11b have the same radial thickness as each other, which is about the same as the radial thickness as the second coils 6′, 6″ shown in FIGS. 1 and 2.

The first superconducting magnet 10 and the second superconducting magnet 30 of the example shown in FIG. 3 are independent current circuits from each other. In the example shown in FIG. 3 this is achieved by a first power supply 40 and a second power supply 50, which are independent of each other, for the first superconducting magnet and second superconducting magnet respectively. The first and second power supplies are connected in a suitable manner to each magnet to provide power to operate the magnets. Additionally, while shown in FIG. 3 in close proximity to the superconducting magnets, the power supplies would be located in a conventional location for a superconducting magnet power supply. This is typically outside of the volume within which the magnetic fields able to be generated by superconducting magnets are able to affect electrical items.

By operating as independent current circuits, the first superconducting magnet 10 and second superconducting magnet 30 of the example shown in FIG. 3 generate independent magnetic fields in use. These combine to generate a resultant magnetic field in a target region of about 1 cm dsv centred on the axial centre of the central axis 20. The homogeneity of the resultant magnetic field in this target region when the magnet system 1 is operating as intended, is shown in Table 5:

TABLE 5

| Magnet | | | | | | | | | |
|---|---|---|---|---|---|---|---|---|---|
| section | Iₒₚ (A) | Z1 | Z2 | Z3 | Z4 | Z5 | Z6 | Z7 | Z8 |
| 10 | 135 | 0 | 4 | 0 | 0 | 0 | 0 | 0 | 0 |
| 30 | 350 | 0 | −3 | 0 | 0 | 0 | 0 | 0 | 0 |
| 1 | | 0 | 1 | 0 | 0 | 0 | 0 | 0 | 0 |

The values shown in Table 5 can be compared to homogeneity of the magnet system 1 when there is a 1 mm axial offset between the first and second superconducting magnets 10, 30 is shown in Table 6:

TABLE 6

| Magnet | | | | | | | | | |
|---|---|---|---|---|---|---|---|---|---|
| section | Iₒₚ (A) | Z1 | Z2 | Z3 | Z4 | Z5 | Z6 | Z7 | Z8 |
| 10 | 135 | 0 | 4 | 0 | 0 | 0 | 0 | 0 | 0 |
| 30 | 350 | 1 | −3 | 0 | 0 | 0 | 0 | 0 | 0 |
| 1 | | 1 | 1 | 0 | 0 | 0 | 0 | 0 | 0 |

As can be seen from Table 6, a 1 mm axial offset of the second superconducting magnet 30 relative to the first superconducting magnet 10 in the example of FIG. 3 produces only 1 ppm/cm in the Z1 harmonic. When compared to Table 5 however, it can be seen the change in the homogeneity of the resultant magnetic field is significantly reduced compared to the example in Table 4, by several orders of magnitude, showing a substantial improvement.

Additionally, since, with or without the axial offset, the homogeneity of the second superconducting magnet 30 is 1 ppm/cm² in the Z2 harmonic. This is due to the configuration of the central, intermediate and outer second coils 8, 9a, 9b, 11a, 11b. It can be seen from Table 6 that it would need more than a 30% fluctuation in operating current to produce a change in homogeneity of greater than 1 ppm/cm² in the Z2 harmonic.

Accordingly, the example shown in FIG. 3 is capable of providing a homogeneity of about 1 ppm over a target region (i.e. a 1 cm dsv) even with an offset of 1 mm. Being able to maintain this level of homogeneity provides a greater reliability in homogeneity and keeps such a magnet system within a specification for magnet systems that sets a limit of 1 ppm on homogeneity, such as in NMR spectrometers. This is achieved through the first magnet 10 and second magnet 30 being independently homogeneous as is possible to provide by being independently compensated. In light of this, the homogeneity of each of the first magnet and second magnet is determined by the arrangement of the solenoids and/or coils of each respective magnet. As such, the first magnet and the second magnet are able to be designed independently of each other to determine their respective homogeneities.

Further examples demonstrate a similar effect to that shown in the example to which Table 5 and Table 6 relates. One such example that can be seen to provide a magnet system according to an aspect disclosed herein uses the same schematic arrangement (although not precisely the same dimensions) described above in relation to FIG. 3, with the same Z1 spherical harmonic components in units of ppm/cm. In this example, if an initial set of Z2 spherical harmonic components in units of ppm/cm\hat{ }² of 15 ppm/cm\hat{ }² for the first superconducting magnet 10 and −5 ppm/cm\hat{ }² for the second superconducting magnet 30 at an operating current, Iₒₚ, of 135 A for the first superconducting magnet and 350 A for the second super conducting magnet, there is a resulting homogeneity in the Z2 spherical harmonic component of 10 ppm/cm\hat{ }². Should a 1 mm axial offset of the second superconducting magnet be present compared to the arrangement for the initial values set out in this paragraph, in a magnet system according to an aspect disclosed herein, there is no change in the homogeneity of the individual superconducting magnets (i.e. the first superconducting magnet and the second superconducting magnet), and only a 1 ppm/cm change in the resulting homogeneity compared to when no offset is present. From this it can be seen that it would need more than a 50% fluctuation in operating current to produce a change in homogeneity of greater than 3 ppm/cm\hat{ }² in the Z2 harmonic. This again demonstrates the significant improvement compared to, for example, the arrangement details in relation to Table 4.

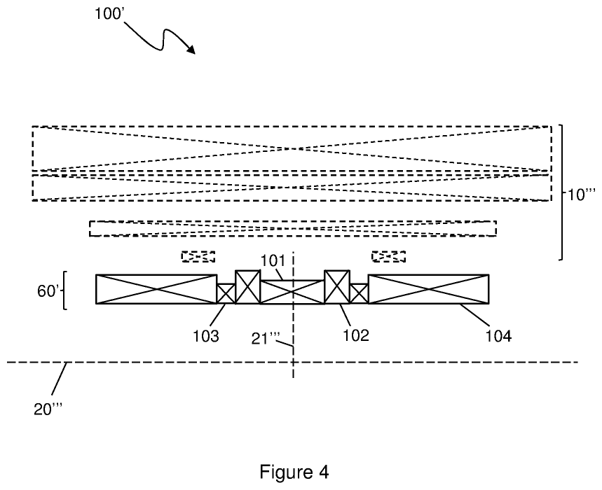

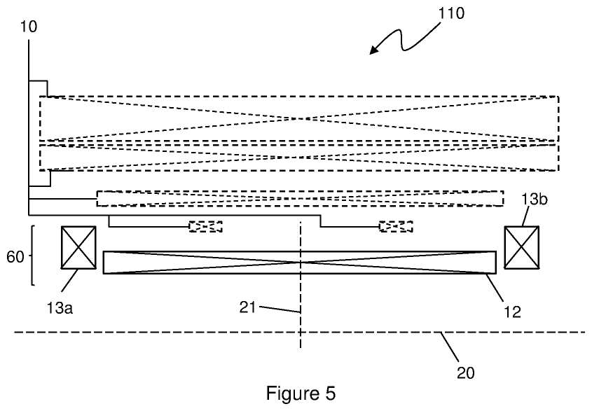

A schematic of a design for a second magnet is illustrated at 60′ in FIG. 4, provided as a comparative example to the example of FIG. 3. This figure generally illustrates a magnet system 100′. This system has a first magnet 10″ corresponding to the first magnet of, for example, FIG. 3. However, the details of that magnet are not of relevance to the details of the second magnets described in relation to FIGS. 4 to 9, so are shown in dashed lines in FIGS. 4 and 5, and in these figures only. This is to demonstrate that such a magnet is able to be present in conventionally designed systems and systems according to aspects disclosed herein (i.e. such as in the example systems shown in FIGS. 5 to 9), but does not affect the functionality or configuration of the magnets described in relation to those figures.

In FIG. 4, the second magnet 60′ has seven coils. These are each coaxially wound around the central axis 20″ and are connected in series with each other. In the example shown in FIG. 4, each of the seven coils is formed of HTS material.

The seven coils of the second superconducting magnet 60′ in the example of FIG. 4 includes a central coil 101. The axial centre of this coil is aligned with the axial centre marked by dashed line 21″ that intersects with the dashed line 20″ making the central axis of the magnet system shown in FIG. 4. This intersection marks the axial and geometric centres of the magnet system 100′ shown in FIG. 4.

At each axial end of the central coil 101 there are first intermediate coils 102. The radial inner side of these coils is aligned with the radial inner side of the central coil. In this position the first intermediate coils are at approximately the same axial position as the radial position of the central coil is positioned from the central axis 20″. This is a natural positioning of the first intermediate coils. This is because it is close to the “Helmholtz coil” position, in order to provide the ability to balance higher order axial harmonics.

In terms of other details regarding the position and arrangement of the first intermediate coils 102, each of the first intermediate coils extends radially outward further than the central coil 101, and have an axial extent of about a third of the axial extent of the central coil. As a proportion of the central coil radial extent, the first intermediate coils extend about a quarter to a third further radially outward than the central coil.

At the axially outer end of each first intermediate coil 102, the second magnet 60′ has a second intermediate coil 103. As with the first intermediate coils, the radial inner side of these coils is aligned with the radial inner side of the central coil 101. Each of the second intermediate coils extends radially outward less than the central coil, and has an axial extent of about the same as the axial extent of each first intermediate coil. As a proportion of the central coil radial extent, the second intermediate coils extend about a quarter to a third less radially than the central coil.

There is an outer coil 104 located at the axial outer end of each second intermediate coil 103. The radial inner side of these coils is aligned with the radial inner side of the central coil 101. Each of the outer coils extend radially outward further than the central coil and extend radially outward less than the first intermediate coils 102. The axial extent of the outer coils, in the example shown in FIG. 4, is about double the axial extent of the central coil. In other examples, the axial extent of the outer coils can be different. This can be a lesser axial extent than shown in FIG. 4 or more, such as about three or about four times the axial extent of the central coil.

The arrangement of the coils in the example shown in FIG. 4 is an example of a known “notched coil” scheme usually constructed from pancake coil stacks. In use, this provides a magnetic field in a target region that is homogeneous, such as being homogeneous at the intersection of the intersection of the central axis 20′″ and the axial centre line 21″, also referred to as the “centre point”. While this could be used in place of the second magnet 30 of FIG. 3, due to the notched arrangement there is a low density of coil turns near this centre point relative to, for example, the second magnet 60 in the example magnet system 110 of FIG. 5. This reduces the field strength and makes it more difficult to balance the coils (i.e. to balance the contribution of each of the central coil, first and second intermediate coils and outer coils) to achieve a target homogeneity. As an example of this, when the coils are connected in series and have the same turns density as each other, if there is a 1 mm axial or radial misplacement of, for example, one of the first intermediate coils, this can result in a inhomogeneity of about a 500 ppm/cm in the Z1 spherical harmonic and about 10 to 20 ppm/cm³ in the Z3 spherical harmonic. Additionally, and also of concern for such a magnet system, this generates inhomogeneity at high spherical harmonic orders, such as about 0.2 to 0.7 ppm/cm⁵ in the Z5 spherical harmonic.

As a further example, an axial displacement of one of the first intermediate coils by about 0.5 mm produces an inhomogeneity of about 60 ppm/cm² in the Z2 spherical harmonic, about 10 ppm/cm³ in the Z3 spherical harmonic, and greater than 0.1 ppm/cm⁴ and 0.1 ppm/cm⁵ respectively in the Z4 and Z5 spherical harmonics. The contribution to the Z2 spherical harmonic comes from the change in contribution to the Z3 spherical harmonic compared to the other (and therefore oppositely positioned balancing) first intermediate coil.

It is worth noting that, while only axial orders of spherical harmonics (i.e. orders along the Z-axis, such as Z1 to Z8) are generally considered herein, an inhomogeneity generated by misplacement of current density compared to the placement as intended by the design of such a magnet system will not be restricted to these on-axis (i.e. along the Z-axis) components. Correcting for unwanted off-axis components arising from this in some cases can be more troublesome than correcting for on-axis components, so would ideally be avoided.

The reasons the example shown in FIG. 4 is considered to be a sub-optimal arrangement by itself relative to the examples shown in FIGS. 5 to 9 is that, it can be shown that the variation in a spherical harmonic evaluated at a target position is proportional to the relative offset of the current loop from its intended position (δb), inversely proportional to the distance of that current loop from the target position (r₀) and proportional to the higher order spherical harmonic(s) generated by the current loop in its intended position, as evaluated at the target position. This means that, for instance, axial misalignment of a coil designed to correct for Z2 inhomogeneity might introduce a significant amount of unintended Z1 inhomogeneity when there is displacement of a coil, such as displacement of one of the first intermediate coils 102 shown in FIG. 4.

In view of this we have found however that by increasing the distance of coils from the centre point, far less unintended change in homogeneity results. As the strength of the higher order terms in the inhomogeneity expansion reduces more quickly with distance than 1/r₀ so that the effect is even more pronounced for unwanted higher order terms. Regarding suitable distances to increase the coils to, we have found that by positioning coils as set out in equation 1 and equation 2 below, the change in homogeneity caused by a displacement of a coil is diminished to an extent that is acceptable.

A suitable position of coils can therefore be considered to be:

$$\sqrt{{( {r}_{p} )}^{2} + {( {z}_{p} )}^{2}} > 2 {r}_{0} \qquad Eq . 1$$

where r₀ is the inside radius of a central coil and, rₚ is the radius of the centre of the a compensation coil, and zₚ is the axial position of the centre of that coil, or

$$\sqrt{{( {r}_{p} )}^{2} + {( {z}_{p} )}^{2}} > 3 {r}_{0} \qquad Eq . 2$$

However, realistic positioning of coils and an ability to achieve a suitable field strength and homogeneity needs to be achieved. We have found that an arrangement of a layer-wound tape solenoid coil with pancake coils provided as compensation coils wound separately to the layer-wound coil with the pancake coils positions on a greater radius from a central axis than the inside radius of the layer-wound solenoid provides such an arrangement. Examples of such arrangements are shown in FIGS. 5 to 9.

Starting with the example magnet generally illustrated at 110 in FIG. 5, as set out above, this has a first magnet 10 comparable to the first magnet 10 of the example magnet system 1 of FIG. 3. Radially inward of the first magnet is a second magnet 60. This has a layer-wound solenoid coil 12 wound coaxial with a central axis 20 and arranged symmetrically relative to an axial centre marked by dashed line 21 in the figure that intersects with the central axis.

The example shown in FIG. 5 also has a pair of compensation coils 13a, 13b connected in series with the solenoid coil 12 forming part of the second magnet 60. These compensation coils and are forward wound, along with the solenoid coil. This enables them to contribute a positive central zeroth order field.

The compensation coils 13a, 13b are wound coaxially with the central axis 20. Instead of being layer-wound solenoid coils, which are more complex to manufacture, these coils are constructed from stacks of pancakes (the coils so constructed referred to hereafter as “pancake coils”). These are located with one pancake coil positioned at each axial end of the solenoid coil. In the example shown in FIG. 5, the pancake coils are located axially outward of the solenoid coil and have a separation between the axial ends of the solenoid coil and each pancake coil.

Regarding radial position and extent of the pancake coils 13a, 13b, the radial inside of each pancake coil 13a, 13b is radially outward of the radial inside of the solenoid coil 12. In the example shown in FIG. 5, the radial inside of the pancake coils is radially inward of the radial outside of the solenoid coil. The radial extent of the pancake coils is about two to three times the radial extent of the solenoid coil.

The solenoid coil 12 and pancake coils 13a, 13b are formed of HTS material. The pancake coils are formed of HTS tape. This has an effect on the axial extent of each pancake coils, since the width of these coils then depends on the width of the tape and the number of pancakes in the stack for any one pancake coil.

A typical HTS tape radial width is between about 0.5 mm and 1 mm. The axial width of HTS tape is typically 8 mm to 10 mm. As such, in a first example corresponding to the example shown in FIG. 5, the pancake coils 13a, 13b each have an axial width of about 3 cm. Accordingly, each pancake coil is a stack of three pancakes.

In a second example corresponding to the example shown in FIG. 5, the pancake coils 13a, 13b each have twice the turns density of the pancake coils 13a, 13b of the first example, which is able to be achieved when using HTS tape with half the axial width. This would result in pancake coils with an axial width of about 1.5 cm.

It is possible to double the turns density between the first example and second example because the field strength at the ends of the second magnet 60 where the pancake coils are located is less than in the centre. This equates to a higher critical current density being possible for the same material and hence allowing a higher operational current density while maintaining the second magnet in its superconducting state.

In use, the layer-wound solenoid coil 12 of the second magnet 60 produces the majority of the zeroth order spherical harmonic (i.e. Z0) magnetic field in the target region, i.e. the Bz component of the field. This is also achieved with better control over the inhomogeneity introduced than the notched magnet 60′ shown in the example of FIG. 4. In addition to this, the pancake coils 13a, 13b make a much smaller contribution to the zeroth order central field due to their positioning. At the level of homogeneity required, this is achieved with the same amount of higher order magnetic field terms, of reversed sign in order to cancel inhomogeneity introduced by the layer-wound solenoid coil.

It would be possible to construct a magnet geometry, which, on page, achieves this. However, there will still be small deviations in the current density from the pancake coils, such as due to manufacturing tolerances. This would still cause the same problem of unbalanced homogeneity as is present in known notched magnets, such as the example shown in FIG. 4. Such a geometry would be one with a layer-wound solenoid with a very narrow set of pancake coils near the centre. Such a set of narrow pancake coils could contribute very little to the zeroth order compared to a long layer-wound solenoid and still nominally correct for the homogeneity. However, in practice, such a set of narrow pancake coils would introduce further higher-order uncorrected field inhomogeneity terms.

We have found that by providing a second magnet 60, such as one corresponding to the example shown in FIG. 5, in line with the inequality set out in equations 1 and 2, an improvement in homogeneity control can be achieved in practice as well as on paper. For example, using an example corresponding to the example shown in FIG. 5 with the pancake coils according to the first example set out above, in the target region a homogeneity of less than 1 ppm can be achieved with the largest factor being the gradient in the Z2 spherical harmonic of less than 1 ppm/cm².

For such an example, with an offset of 1 mm axially or radially for one of the pancake coils 13a, 13b, an inhomogeneity is generated of only about 30 ppm/cm in the Z1 spherical harmonic and about 0.2 ppm/cm³ in the Z3 spherical harmonic. Similar results are achieved if multiple stacks are used for each pancake coil. As can be seen by comparing these homogeneities to those disclosed above for the example shown in FIG. 4, this is a considerable improvement in homogeneity.

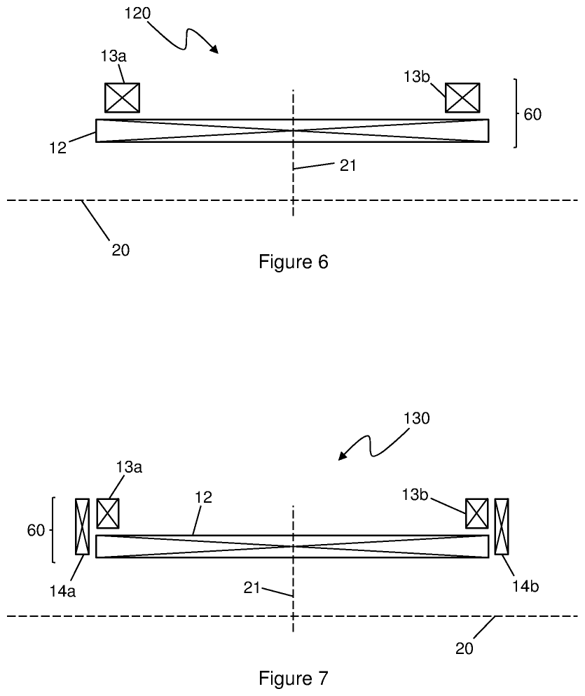

From this it can be seen that the example shown in FIG. 5 provides greater benefits than the example shown in FIG. 4. As such, the second magnet 60′ of FIG. 4, would not be an optimal system to use by itself as part of the magnet system 110 shown in FIG. 5. However, it could be used in place of the solenoid coil 12 of the examples shown in FIG. 5, or, as demonstrated below, of any of the examples shown in FIGS. 6 to 9, which are described in more detail below, with the compensation coils suitably located. If this were carried out, the combined system would produce similar improved homogeneity over the homogeneity achievable when only using second magnet shown in FIG. 4.

The examples shown in FIGS. 6 to 9 provide comparable results to those set out for an example of FIG. 5. Considering the example shown in FIG. 6 first, this has a magnet system generally illustrated at 120. As well as a first magnet (not shown), this has a second magnet 60.

The second magnet 60 shown in FIG. 6 has an identical layer-wound solenoid coil 12 to the layer-wound solenoid coil 12 of the example shown in FIG. 5. As such, this is coaxially wound on a central axis 20 and is axially symmetric about the axial centre marked by dashed line 21.

In the example shown in FIG. 6, there are pancake coils 13a, 13b connected to the solenoid coil 12 in the same manner as in the example shown in FIG. 5 (i.e. in series) and have the same functionality. As with the pancake coils of FIG. 5, the pancake coils shown in FIG. 6 are coaxially wound on the central axis 20. However, instead of being located axially outwardly of the solenoid coil, one pancake coil is located adjacent each axial end region of the solenoid coil (i.e. axially inward of and within about half the width each pancake coil of the axial end of the solenoid coil). This locates the pancake coils at an axial position of about three to four times the radial position of the radial inside of solenoid coil.

Additionally, in the example shown in FIG. 6, the pancake coils 13a, 13b are located radially outwardly of the radial outside of the solenoid coil 12. In FIG. 6 there is a radial separation between the solenoid coil and the pancake coils. The radial positioning of the pancake coils provides a radial positioning approaching a factor of two further radially outward than the radial inside of the solenoid coil.

In relation to the example of FIG. 6, in an example where the pancake coils have a width of about 3 cm (i.e. having a similar structure to the first example described in relation to FIG. 5 above), when an axial offset of 0.5 mm of one of the pancake coils 13a, 13b is present, this produces an inhomogeneity of only 2 ppm/cm² in the Z2 spherical harmonic, 0.1 ppm in the Z3 spherical harmonic and a negligible (so significantly less than 0.1 ppm/cm⁴ and 0.1 ppm/cm⁵ respectively) in the Z4 and Z5 spherical harmonics. The Z2 spherical harmonic reduction relative to the comparable value in the example of FIG. 4 again comes from the change in contribution of Z3 compared to the oppositely positioned balancing pancake coil in this case being much smaller than in the example of FIG. 4.

The example shown in FIG. 7 is comparable to a combination of the examples shown in FIGS. 5 and 6. This, as generally illustrated at 130, shows a magnet system. In addition to a first magnet (not shown), this has a second magnet 60.

The second magnet 60 in the example shown in FIG. 7 has an identical layer-wound solenoid coil 12 to the layer-wound solenoid coil 12 of the example shown in FIG. 5 and as shown in FIG. 6. As such, this is coaxially wound on a central axis 20 and is axially symmetric about the axial centre marked by dashed line 21.

In the example shown in FIG. 7, there are two pairs of pancake coil stacks. This comprises a pair of axially inner pancake coil stacks 13a, 13b and a pair of axially outer pancake coil stacks 14a, 14b. Each pair of pancake coils stacks is a set of one or more pancake coils coaxially wound on the central axis 20.

The axially inner pancake coils 13a, 13b are in approximately the same axial and radial position as the pancake coils of the example shown in FIG. 6. In some variations of the example shown in FIG. 6, the axially outer ends of the axially inner pancake coils are aligned with the axially outer ends of the solenoid coil 12.

The axially outer pancake coils 14a, 14b are located in approximately the same axial and radial position as the pancake coil of the example shown in FIG. 5. Due to there being two pairs of pancake coils in the example shown in FIG. 7 however, the axial extent of each pair is able to be less than the comparable pancake coils of FIGS. 5 and 6 as the two pairs each provide compensation. This means each pair needs to provide less compensation than if there was only a single pair of pancake coils providing compensation. This is due to the cumulative effect of the compensation the two pairs of compensation coils will provide in use.

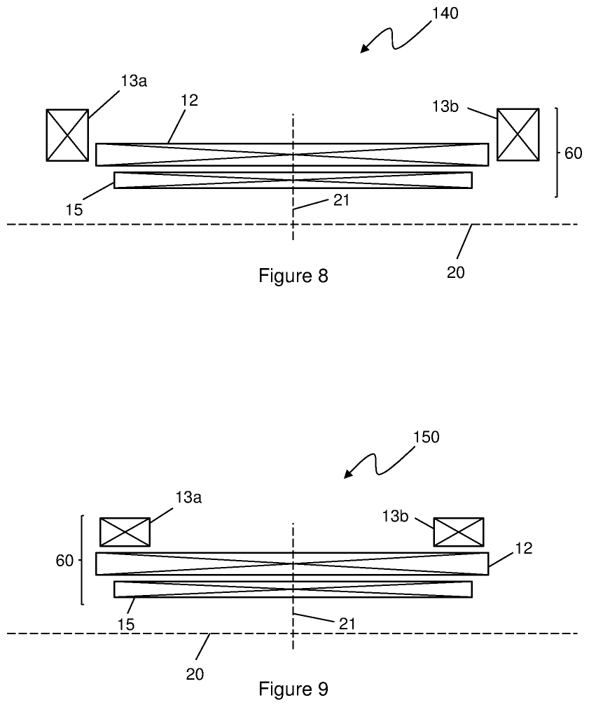

Turning to the examples shown in FIGS. 8 and 9, these generally illustrate magnet systems respectively at 140 and 150, each with a second magnet 60 (as well as a first magnet, which is not shown). Each of these examples provide pancake coils 13a, 13b arrangements comparable to the pancake coils examples shown in FIGS. 5 and 6 respectively. This means that in each example the pancake coils are coaxially wound on a central axis 20. For the example of FIG. 8, this means the pancake coils are located axially outwardly of a layer-wound solenoid coil 12 with a radial inside slightly radially inward of the radial inside of the radial inside of the solenoid coil. In the example of FIG. 9, this means the pancake coils are located radially outward of the radial outside of a layer-wound solenoid coil 12 at an axial end region of the solenoid coil.

However, while the axial and radial positioning of the pancake coils 13a, 13b is approximately the same in FIG. 8 as in FIG. 5 and in FIG. 9 as in FIG. 6, each pancake coil in FIG. 8 and FIG. 9 is a larger size. This is because the second magnet of each examples also includes an inner solenoid coil 15, and therefore additional compensation is provided therefore by the respective pancake coils. The inner solenoid coil in each example is located radially inward of the layer-wound solenoid coil 12.

In the examples shown in FIGS. 8 and 9, the inner solenoid coil 15 is coaxially wound on the central axis with the layer-wound solenoid coil 12 to which it is connected in series. Additionally, the layer-wound solenoid coil and the inner solenoid coil are positioned axially so they are symmetric about the axial centre marked by dashed line 21. The inner solenoid however has an axial extent of about 80% to 90% of the layer-wound solenoid coil and has a comparable reduction of its radial extent relative to the layer-wound solenoid coil.

The pancake coils 13a, 13b of the examples of FIGS. 8 and 9 are larger than, and have slightly different positions from, the pancake coils of the examples of FIGS. 5 and 6. As set out above, this is in order for the pancake coils 13a, 13b of the examples of FIGS. 8 and 9 to compensate the axial inhomogeneities of the complete second magnet 60 with the current in series through all coils.

The inner solenoid coil 15 of the examples of FIGS. 8 and 9 is formed of HTS material. In some examples, this coil is layer-wound tape or wire. This coil need not be from the same material as the layer-wound solenoid coil 12. For instance, in various examples, the layer-wound solenoid coil 12 is BSCCO tape and the inner solenoid coil 15 is wind-and-react BSCCO round wire.

The second magnet 60 of each example of each of FIGS. 5 to 9 is able to be used in place of the second magnet 30 of examples according to FIG. 3. As such, while not shown in FIGS. 5 to 9, the second magnets of each example replace all the coils 5, 8, 9a, 9b, 11a, 11b of examples according to FIG. 3 and are located in approximately the same axial and radial positions as those coils. For the examples where the pancake coils 13a, 13b are located radially outwardly of a layer-wound solenoid coil 12, these would be located axially outwardly of the compensation coils 7a, 7b of the first magnet 10 in various examples. Further, when taking the place of second magnet 30 of examples according to FIG. 3, the second magnet 60 of examples according to each of FIGS. 5 to 9 is connected to a second power supply 50 independent of a first power supply 40 of the first magnet 10. Accordingly this forms an independent current circuit for the second magnet 60 of examples according to each of FIGS. 5 to 9 from any first magnet.

The example magnet systems described above are axially symmetric about a centre point (i.e. at z=0). The concepts the example magnet systems embody and corresponding analysis of those systems are also applicable to asymmetric solutions (i.e. solutions that are asymmetric about the centre point).

1. A magnet system for generating a homogeneous magnetic field in a target region, the magnet system comprising:
a first magnet formed from low temperature superconductor, LTS, material and formed so as to define a central axis, the first magnet being arranged in use to generate a first magnetic field in the target region located upon the central axis, the first magnetic field having a first level of homogeneity;
a second magnet formed from high temperature superconductor, HTS, material and arranged in use to generate a second magnetic field in the target region, the second magnetic field having a second level of homogeneity, wherein
the first level of homogeneity of the first magnetic field is up to 10 parts per million, ppm, and the second level of homogeneity of the second magnetic field is up to 10 ppm, the combination of the first and second magnetic fields in the target region generating in use a resultant magnetic field having a resultant homogeneity of up to 10 ppm, and wherein the first magnet and second magnet are independent current circuits.

2. The magnet system according to claim 1, wherein the first level of homogeneity is up to 1 ppm, the second level of homogeneity is up to 1 ppm and the resulting homogeneity is up to 1 ppm.

3. The magnet system according to claim 1, further comprising a control system arranged to provide a first current in the first magnet, and a second current in the second magnet, and wherein the first and second currents are controlled independently of each other.

4. The magnet system according to claim 1, further comprising a first power supply arranged in use to provide power to the first magnet and a second power supply arranged in use to provide power to the second magnet, the first power supply and second power supply being independent of each other.

5. The magnet system according to claim 1, wherein the first magnet comprises a first compensated solenoid magnet.

6. The magnet system according to claim 5, wherein the first compensated solenoid magnet comprises at least one solenoid and a set of first compensation coils, the set of first compensation coils being arranged in use to compensate the at least one solenoid.

7. The magnet system according to claim 1, wherein the second magnet comprises a set of coils.

8. The magnet system according to claim 7, wherein the second magnet comprises a set of coils located upon the central axis.

9. The magnet system according to claim 1, wherein the second magnet comprises a second compensated solenoid magnet, including at least one solenoid and a set of second compensation coils which are operated in use so as to provide compensation to the at least one solenoid, and the set of second compensation coils are located according to
$$\sqrt{{( {r}_{p} )}^{2} + {( {z}_{p} )}^{2}} > 2 {r}_{0}$$
where r₀ is the inside radius of the at least one solenoid and, rₚ is the radius of the centre of the a respective compensation coil, and zₚ is the axial position of the centre of said compensation coil.

10. The magnet system according to claim 9, wherein the set of second compensation coils are located according to
$$\sqrt{{( {r}_{p} )}^{2} + {( {z}_{p} )}^{2}} > 3 {r}_{0} .$$

11. The magnet system according to claim 9, wherein the at least one solenoid of the second compensated solenoid magnet comprises a primary solenoid coil extending from the axial centre symmetrically axially away from the target region, the set of second compensation coils being pancake coils and located adjacent the primary solenoid coil at axial ends of the primary solenoid coil.

12. The magnet system according to claim 11, wherein r₀ is the inside radius of the primary solenoid coil.

13. The magnet system according to claim 9, wherein the at least one solenoid of the second compensated solenoid magnet includes a secondary solenoid coil arranged coaxially upon the central axis with respect to the primary solenoid coil and radially inwardly of the primary solenoid coil.

14. The magnet system according to claim 9, wherein the second compensation coils comprising a compensation coil located axially outwardly of each end of the primary solenoid coil with at least a partial radial overlap with the primary solenoid coil and/or a compensation coil located radially outwardly of the primary solenoid coil at each axial end of the primary solenoid coil.

15. The magnet system according to claim 9, wherein each second compensation coil is forward wound relative to the primary solenoid coil.

16. A magnet system for generating a homogeneous magnetic field in a target region, the magnet system comprising:
a first magnet formed from a superconducting material in a cylindrical shape around with a central axis, the first magnet being arranged in use to generate a first magnetic field in the target region located upon the central axis;
and
a set of compensation coils which are operated in use so as to provide the homogeneity of the first magnetic field, wherein the first magnet extends from the axial centre symmetrically axially away from the target region and the set of compensation coils are pancake coils located according to
$$\sqrt{{( {r}_{p} )}^{2} + {( {z}_{p} )}^{2}} > 2 {r}_{0}$$
where r₀ is the inside radius of the first magnet and, rₚ is the radius of the centre of the a respective pancake coil, and zₚ is the axial position of the centre of said pancake coil.

17. The magnet system according to claim 16, wherein the set of compensation coils are located adjacent the first magnet at axial ends of the first magnet.

18. The magnet system according to claim 17, wherein the compensation coils comprising a compensation coil located axially outwardly of each end of the first magnet with at least a partial radial overlap with the first magnet and/or a compensation coil located radially outwardly of the first magnet at each axial end of the first magnet.

19. The magnet system according to claim 16, further comprising a second magnet arranged coaxially upon the central axis with respect to the first magnet and radially inwardly of the first magnet.

20. (canceled)

21. The magnet system according to claim 16, wherein each second compensation coil is forward wound relative to the primary solenoid coil.
